(19) United States
(12) Patent Application Publication
(10) Pub. No.: US 2005/0037598 A1
(43) Pub. Date: Feb. 17, 2005

(54) Method for producing polycrystalline silicon germanium and suitable for micromachining

(76) Inventor: Ann Witvrouw, Herent (BE)

Correspondence Address: KNOBBE MARTENS OLSON & BEAR LLP, 2040 MAIN STREET, FOURTEENTH FLOOR, IRVINE, CA, 92614, US

(21) Appl. No.: 10/835,082

(22) Filed: Apr. 28, 2004

Related U.S. Application Data
(60) Provisional application No. 60/466,844, filed on Apr. 29, 2003.

(30) Foreign Application Priority Data
May 28, 2003 (EP) EP 03447127.6

(51) Int. Cl. H01L 21/20

(52) U.S. Cl. 438/488

(57) ABSTRACT

The invention relates to methods for preparing as-deposited, low-stress and low resistivity polycrystalline silicon-germanium layers and semiconductor devices utilizing the silicon-germanium layers. These layers can be used in Micro Electro-Mechanical Systems (MEMS) devices or micro-machined structures.

### RELATED APPLICATION

This application claims the benefit of U.S. Provisional Application No. 60/466,844, filed Apr. 29, 2003.

### FIELD OF THE INVENTION

The invention relates to methods for preparing as-deposited, low-stress and low resistivity polycrystalline silicon-germanium layers and semiconductor devices utilizing the silicon-germanium layers. These layers can be used in Micro Electro-Mechanical Systems (MEMS) devices or micro-machined structures.

### BACKGROUND OF THE INVENTION

Micro Electro-Mechanical Systems (MEMS) are used in a wide variety of systems such as accelerometers, gyroscopes, infrared detectors, micro turbines, and the like. For high volume applications, fabrication costs can potentially be reduced by monolithic integration of MEMS with the driving electronics. For 2D imaging applications, such as detectors and displays, monolithic integration of MEMS and CMOS processing is a desirable solution as this simplifies the interconnection issues. The easiest approach for monolithic integration is post-processing MEMS on top of the driving electronics, as this does not introduce any change in the standard fabrication processes used for preparing the driving electronics. It also allows the preparation of a more compact micro-system. This is not possible if the MEMS device is produced prior to the formation of the driving electronics. On the other hand, post processing imposes an upper limit on the fabrication temperature of MEMS to avoid any damage or degradation in the performance of the driving electronics. This upper limit on temperature is typically 450° C. An overview of several approaches for the integration of driving electronics and MEMS devices can be found in ‘Why CMOS-integrated transducers? A review’, Microsystem Technologies, Vol. 6 (5), p 192-199, 2000, by A. Witvrouw et al.

For many micromachined devices, such as transducers and other freestanding structures, the mechanical properties of the applied thin films can be critical to their success. For example, stress or stress gradients can cause freestanding thin-film structures to warp to the point that these structures become useless. Such thin film layers ideally have a low stress and a zero stress gradient. If the stress is compressive (indicated by a minus sign (−)), structures can buckle. If the tensile stress is too high (indicated by a plus sign (+)), structures can break. If the stress gradient is different from zero, microstructures can deform, for example, cantilevers can bow.

Polycrystalline silicon (poly Si) has been widely used for MEMS applications. The main disadvantage of this material is that it requires high processing temperatures, namely, higher than 800° C., to achieve the desired physical properties, especially properties related to stress, as explained in “Strain studies in LPCVD polysilicon for surface micromachined devices,” Sensors and Actuators A (physical), A77 (2), p. 133-8 (1999), by J. Singh et al. Accordingly, poly Si MEMS applications can not be used for integration with CMOS if the CMOS is processed before the MEMS device.

Polycrystalline silicon germanium (poly SiGe) is known in the art as an alternative to poly Si as it has similar properties. The presence of germanium reduces the melting point of the silicon germanium alloy, and hence the desired physical properties can be achieved at lower temperatures, allowing the growth on low-cost substrates such as glass. Depending on the germanium concentration and the deposition pressure, the transition temperature from amorphous to polycrystalline can be reduced to 450° C., or even lower, compared to 580° C. for CVD poly Si.

A functional poly SiGe layer for use in microstructure devices, such as gyroscopes, accelerometers, micro-mirrors, resonators, and the like, which are typically from about 3 μm to about 12 μm thick, requires low-stress (<20 MPa compressive and <100 MPa tensile) and low electrical resistivity. An important factor for industrial applicability is that it is possible to produce these layers at a relatively high deposition rate. A reasonably small variance of characteristics between different points on the wafer is preferably also achieved.

U.S. Appl. No. 10/263,623, filed Oct. 3, 2003, now U.S. Pub. No. 2003-0124761-A1, the contents of which are hereby incorporated by reference in their entirety, deals with the development of low-stress poly-SiGe layers under different deposition parameters. Some deposition parameters studied include, for example, the deposition temperature, the concentration of semiconductors (e.g., the concentration of silicon and germanium in a SiₓGe₁₋ₓ layer, with x being the concentration parameter), the concentration of dopants (e.g., the concentration of boron or phosphorous), the amount of pressure, and the use of plasma.

Fast deposition methods such as PACVD (Plasma Assisted Chemical Vapor Deposition) or PECVD (Plasma Enhanced Chemical Vapor Deposition) having a typical deposition rate greater than about 100 nm/min typically yield amorphous layers with high stress and high resistivity at temperatures compatible with CMOS (450° C. or lower), at low germanium concentrations. Polycrystalline layers deposited with PECVD with low stress and low resistivity are described in WO01/74708, but are deposited only at high temperatures (above 550° C.).

Slow deposition methods such as CVD, with typical deposition rates of from about 5 to about 15 nm/min, can yield crystalline layers with a low resistivity at 450° C., but this is generally not an economical process in a single wafer tool for, e.g., 10 μm thick layers, since the processing time is long. In WO01/74708 it is indicated that the CVD deposition of in situ boron doped polycrystalline SiGe at lower temperature (about 400° C.) is feasible if the Ge concentration is sufficiently high (above 70%) and if the boron concentration is sufficiently high (above 10¹⁹/cm³).

### SUMMARY OF THE INVENTION

A deposition process for preparing polycrystalline-SiGe layers and devices while preferably improving stress and/or resistivity and/or speed of deposition is desirable.

Accordingly, in a first embodiment a method of producing a polycrystalline SiGe layer on a substrate is provided, the method including depositing onto the substrate a first layer including polycrystalline silicon-germanium, wherein the depositing includes non-plasma chemical vapor deposition conducted at a first temperature less than or equal to about 520° C.; and depositing onto the first layer a second layer including polycrystalline silicon-germanium, wherein the depositing includes plasma enhanced chemical vapor deposition or plasma assisted chemical vapor deposition at a second temperature less than or equal to about 520° C., whereby a polycrystalline SiGe layer including the first layer and the second layer is obtained.

In an aspect of the first embodiment, the method further includes depositing a nucleation layer onto the substrate at a third temperature less than or equal to about 520° C., wherein the depositing is conducted before depositing the first layer.

In an aspect of the first embodiment, the nucleation layer includes silicon or SiₓGe₁₋ₓ wherein 0.10≦x.

In an aspect of the first embodiment, the first layer includes Si_{y}Ge_{1-y} wherein 0.10≦y≦1.

In an aspect of the first embodiment, the first layer includes Si_{y}Ge_{1-y} wherein 0.50≦1-y≦0.70.

In an aspect of the first embodiment, the second layer includes Si_{z}Ge_{1-z} wherein 0.10≦z≦1.

In an aspect of the first embodiment, the second layer includes Si_{z}Ge_{1-z} wherein 0.50≦1-z≦0.70.

In an aspect of the first embodiment, the first temperature, the second temperature, and the third temperature are each less than or equal to about 500° C.

In an aspect of the first embodiment, the first temperature, the second temperature, and the third temperature are each less than or equal to about 450° C.

In an aspect of the first embodiment, the first temperature equals the second temperature, and the second temperature equals the third temperature.

In an aspect of the first embodiment, the first temperature equals the second temperature, the second temperature equals the third temperature, and the third temperature equals about 450° C.

In an aspect of the first embodiment, the second layer includes Si_{z}Ge_{1-z} wherein 0.50≦1-z≦0.70.

In an aspect of the first embodiment, the second layer includes Si_{z}Ge_{1-z} wherein 0.60≦1-z≦0.70.

In an aspect of the first embodiment, the steps of depositing the first layer and the second layer are performed at a pressure of from about 1 to about 10 Torr.

In an aspect of the first embodiment, a plasma power is from about 10 to about 100 W.

In an aspect of the first embodiment, a plasma power density is from about 20 to about 200 mW/cm².

In an aspect of the first embodiment, the polycrystalline SiGe layer has an electrical resistance of less than about 10 mΩcm.

In an aspect of the first embodiment, the polycrystalline SiGe layer has a compressive stress of less than about 20 MPa and a tensile stress of less than about 100 MPa.

In a second embodiment, a method of producing a SiGe layer on a substrate is provided, the method including depositing onto the substrate a first layer including a polycrystalline silicon-germanium by a non-plasma chemical vapor deposition technique at a temperature of less than or equal to 520° C. and at a rate of less than about 10 nm/min; and depositing onto the first layer a second layer including polycrystalline silicon-germanium by a plasma enhanced chemical vapor deposition technique at a temperature of less than or equal to 520° C. and at a rate of about 50 nm/min or more, whereby a polycrystalline SiGe layer including the first layer and the second layer is obtained.

In an aspect of the second embodiment, the step of depositing the second layer is conducted at a rate of about 100 nm/min or more.

### BRIEF DESCRIPTION OF THE DRAWINGS

FIG. 1 shows sensor locations, indicated by numbered positions, on a stressmeter for a 6 inch wafer.

FIG. 2 shows a poly SiGe layer stack in accordance with a preferred embodiment.

FIG. 3 shows variation of average stress with deposition temperature for a poly SiGe layer.

FIG. 4 shows variation of average resistivity with deposition temperature for a poly SiGe layer.

FIG. 5 shows variation of average resistivity with silane flow rate for a poly SiGe layer.

FIG. 6 shows variation of average stress with silane flow rate for a poly SiGe layer.

FIG. 7 includes Scanning Electron Microscope (SEM) images of a MEMS cantilever constructed in a SiGe layer in accordance with a preferred embodiment.

### DETAILED DESCRIPTION OF THE PREFERRED EMBODIMENT

The following description and examples illustrate a preferred embodiment of the present invention in detail. Those of skill in the art will recognize that there are numerous variations and modifications of this invention that are encompassed by its scope. Accordingly, the description of a preferred embodiment should not be deemed to limit the scope of the present invention.

A polycrystalline SiGe (poly SiGe) layer is deposited on top of a substrate, e.g., a substrate comprising a semiconductor material, at a temperature compatible with the underlying material, e.g., at least one semiconductor device made by CMOS processing. In preferred embodiments, the term “substrate” as used herein, is a broad term and is used in its ordinary sense, including, without limitation, to describe any underlying material or materials that can be used, or can contain, or upon which a device such as a MEMS device, a mechanical, electronic, electrical, pneumatic, fluidic or semiconductor component or similar, a circuit or an epitaxial layer can be formed. In various embodiments, the “substrate” can include a semiconductor substrate such as, for example, a doped silicon substrate, a gallium arsenide (GaAs) substrate, a gallium arsenide phosphide (GaAsP) substrate, an indium phosphide (InP) substrate, a germanium (Ge) substrate, or a silicon germanium (SiGe) substrate. The “substrate” can include, for example, an insulating layer such as a SiO₂ or a Si₃N₄ layer in addition to a semiconductor substrate portion. Thus, the term “substrate” also encompasses substrates such as silicon-on-glass and silicon-on sapphire substrates. The term “substrate” is thus used to define generally the elements for layers that underlie a layer or portions of interest. The “substrate” can be any base on which a layer is formed, for example, a glass substrate or a glass or metal layer. As discussed herein, processing is primarily described with reference to processing silicon substrates, but the skilled person will appreciate that the preferred embodiments can be implemented based on other semiconductor material systems, and that the skilled person can select suitable materials as equivalents, as for example, glass substrates.

The thickness of the SiGe layer is preferably from about 0.5 μm or less to about 25 μm or more, preferably from about 0.6, 0.7, 0.8, 0.9, 1, 1.1, 1.2, 1.3, 1.4, 1.5, 1.6, 1.7, 1.8, 1.9, 2, 2.1, 2.2, 2.3, 2.4, 2.5, 2.6, 2.7, 2.8, .2.9, 3, 3.5 4, 4.5, 5, 5.5, 6, 6.5, or 7 μm to about 13, 14, 15, 16, 17, 18, 19, 20, 21, 22, 23, or 24 μm, and more preferably from about 8, 8.5, 9, 9.5 or 10 μm to about 11, 11.5, or 12 μm. It is preferred to maintain a low or controlled stress or a low or controlled stress gradient and a low or controlled resistivity in the deposited SiGe films. In accordance with a preferred embodiment, a polycrystalline SiGe layer is deposited by a combination of Plasma Enhanced Chemical Vapor Deposition (PECVD) or Plasma Assisted Chemical Vapor Deposition (PACVD) and Chemical Vapor Deposition (CVD) processes. The CVD process can be a low pressure up to atmospheric pressure CVD process. The CVD process can be a batch or single wafer process. Preferably, the CVD process is a non-plasma CVD process

The PECVD or PACVD poly SiGe layers are deposited in a suitable deposition system, such as a batch or single wafer system. An example of a suitable system is an Oxford Plasma Technology (OPT) Plasma Lab 100 cold wall system. This system consists of two chambers and a central loadlock system. A SiC-covered graphite plate can be used as a carrier for a substrate or semiconductor wafer to avoid contamination at high temperature. The substrate rests on the chuck, which is the bottom electrode. The reaction gases are fed into the chamber from the top through the top electrode with an integrated shower head gas inlet. A graphite heater heats the chuck to the desired temperature. The calibration for actual wafer temperature can be done in vacuum and at a hydrogen pressure of 2 Torr with a thermocouple wafer, having a number of, e.g. seven, thermocouples. This system provides the advantage that one system can be used for both low pressure CVD and PECVD. The preferred embodiments are not limited to the use of a single system and include use of systems and devices dedicated to one or more of these processing techniques.

For SiGe depositions, the gas flows are preferably fixed at a suitable rate, e.g., 166 sccm 10% GeH₄ in H₂ and 40 sccm 1% B₂H₆ in H₂. The SiH₄ flow rate is preferably varied and the chamber pressure is preferably maintained at a suitable pressure, such as 2 Torr. Films are preferably deposited on (100) Silicon wafers covered with an oxide layer, preferably a thermal oxide layer, e.g., a 250 nm thick thermal oxide. In preferred embodiments, a plasma power of from 10W or less to about 100W or more can be used for the PECVD deposition, preferably from about 10, 15, 20, or 25W to about 40, 50, 60, 70, 80, or 90W, more preferably about 30W. For an electrode diameter of about 25 cm, the plasma power density equals about 60 mW/cm². The plasma power density range is preferably from about 20 mW/cm² or less to about 200 mW/cm² or more, preferably from about 25, 30, 35, 40, 45, 50, 55, 60, 65, 70, 75, 80, 85, 90, 95, or 100 mW/cm² to about 110, 120, 130, 140, 150, 160, 170, 180, or 190 mW/cm². Preferably no plasma power is used for the pure low pressure to atmospheric pressure CVD deposition. The CVD deposition is optionally done on top of a nucleation layer. The nucleation layer is preferably an amorphous seed layer, e.g., a PECVD deposited seed layer, preferably a PECVD deposited amorphous seed layer. Such layers can be employed to avoid large incubation times. A seed layer is not necessarily preferred when a time budget is not an issue. The incubation time can constitute a certain delay in the SiGe layer production. See, e.g., Lin et al., entitled ‘Effects of SiH₄, GeH₄ and B₂H₆ on the Nucleation and Deposition of Polycrystalline Si₁₋ₓGEₓ Films’, J. Electrochem. Soc., Vol. 141, No. 9, September 1994, pp 2559-2563, which discloses values of incubation times at 550° C. and pressures of 0.94-1.95 mTorr, namely, 36 minutes for undoped poly-Si, 51 minutes for undoped poly-SiGe, 3 minutes for B-doped poly-Si, and 2 minutes for B-doped poly-SiGe.

In King et al., ‘Deposition and Properties of Low-Pressure Chemical-Vapor Deposited Polycrystalline Silicon-Germanium Films’, J. Electrochem. Soc., Vol. 141 (8), August 1994, pp 2235-2240, it is disclosed that the incubation time rises with decreasing temperature.

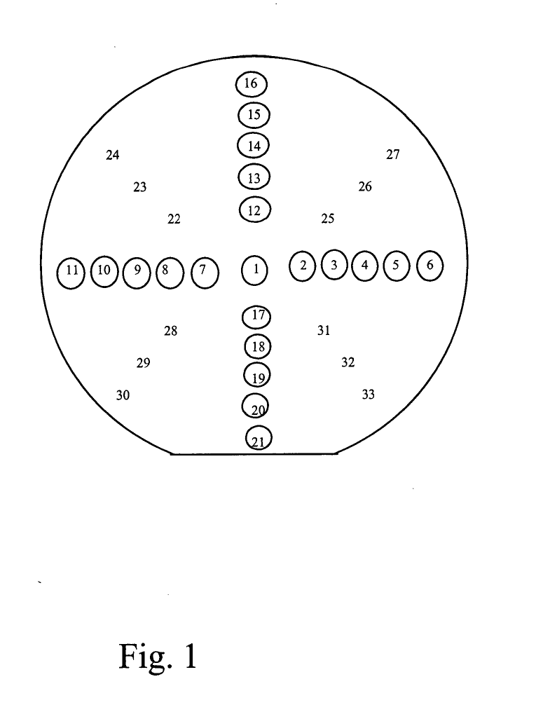

The stress of the SiGe film can be measured using a suitable device, such as an Eichorn and Hausmann MX 203 stressmeter, as depicted schematically in FIG. 1. Sensor locations are indicated by numbered positions. The stressmeter gives the average stress of the film by measuring the bow of the wafer before and after the deposition. The stressmeter has 2×33 sensors, from which 16 local stress values can be measured. For the center stress (Ct), measurements are made on triplets consisting of a center point and two points on the diametrically opposite edges. There are four such triplets on a 6 inch wafer (16-1-21, 24-1-33, 6-1-11, 27-1-30). An average of these values gives the center stress. For the average (Av) stress calculation, triplets are composed of three immediate neighboring points on a radial line. An average of all such triplets is taken to determine the average stress value.

The sheet resistance can be measured over the wafer using a suitable probe, e.g., a four-point probe. Rutherford Backscattering (RBS) measurements can be carried out to measure Si and Ge concentrations in the film.

Any deposited SiGe layer in accordance with the preferred embodiments can be processed by any conventional semiconductor or MEMS processing method. For example, photolithography can be carried out to pattern the as-deposited SiGe layers. For example, the SiGe layer can be etched, e.g., in a Surface Technology Systems plc (STS) deep dry etching system, which uses an SF₆+O₂/C₄F₈ alternating plasma.

Film thickness can be measured using a Dektak surface profiler. Any underlying sacrificial SiO₂ can be removed by a vapor HF etch. The results of different conventional methods are described below, followed by the results of a method according to a preferred embodiment.

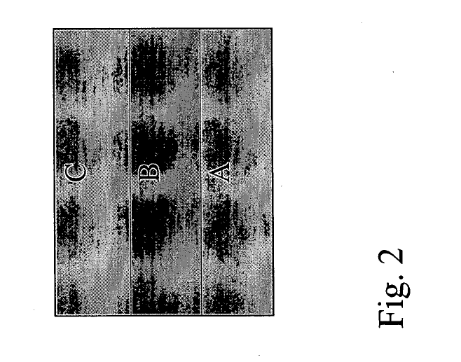

In a preferred embodiment, a combination of CVD and PECVD or PACVD processes can be used to obtain polycrystalline films at a low temperature compatible with, e.g., CMOS processes. FIG. 2 depicts schematically (not to scale) the resulting layers. A nucleation layer A (e.g., a thin PECVD or PACVD layer approximately 94 nm in thickness) is deposited in order to avoid a large incubation time for the growth of SiGe on SiO₂. Nucleation layer B preferably has a thickness of 5 nm or less to about 200 nm or more, more preferably from about 10, 15, 20, 25, 30, 35, 40, 45, 50, 55, 60, 65, 70, 75, 80, 85, 90, 95, or 100 nm to about 110, 120, 130, 140, 150, 160, 170, 180, or 190 nm. The nucleation layer A is believed to be amorphous and acts as a seed layer for the CVD layer B. CVD layer B is deposited on the nucleation layer A. CVD layer B preferably has a thickness of 5 nm or less to about 400 nm or more, more preferably from about 10, 15, 20, 25, 30, 35, 40, 45, 50, 60, 70, 80, 90, 100, 110, 120, 130, 140, 150, 160, 170, 180, 190, 200, 210, 220, 230, 240, 250, 260, 270, 280, 290, 300, 310, 320, 330, 340, or 350 nm to about 360, 370, 380, or 390 rm. The CVD layer B can also act as a crystallization seed layer for a PECVD or PACVD layer C, thus making it possible to obtain a polycrystalline film at low temperatures. The thickness of PECVD or PACVD layer C is preferably from about 50 nm or less to about 700 nm or more, more preferably from about 60, 70, 80, 90, 100, 110, 120, 130, 140, 150, 160, 170, 180, 190, 200, 210, 220, 230, 240, 250, 260, 270, 280, 290, 300, 310, 320, 330, 340, 350, 360, 370, 380, 390 nm, or 400 nm to about 425, 450, 475, 500, 525, 550, 575, 600, 625, 650, or 675 nm. For example, a layer A of thickness of about 94 nm, a layer B of thickness of about 370 nm, and a layer C of thickness of about 536 nm yields a total thickness of about 1 μm. deposited on top of the CVD layer B, thus making it possible to obtain a polycrystalline film at low temperatures. To reduce processing temperatures it is preferred if the percentage of germanium in the SiGe CVD layer is 10% or more. In preferred embodiments, the percentage of germanium in the the poly SiGe layers is an independently selected value of from about 5% or more, preferably from about 6, 7, 8, 9, 10, 11, 12, 13, 14, 15, 16, 17, 18, 19, or 20% to about 25, 30, 35, 40, 45, 50, 55, 60, 65, 70, 75, 80, 85, 90, or 95%, or more. Preferably, the deposition process is conducted at a temperature of about 520° C. or less, more preferably at a temperature of about 515, 510, 505, 500, 495, 490, 485, 480, 475, 470, 465, 460, 455, or 450° C. or less. It is generally preferred that the deposition process is conducted at a temperature of about 300° C. or higher, preferably higher than 305, 310, 315, 320, 325, 330, 335, 340, 345, 350 or higher, more preferably 355, 360, 365, 370, 375, 380, 385, 390, 395, 400, 405, 410, 415, 420, 425, 430, 435, 440, or 445° C. or higher. The growth speed at a temperature of 400° C. is about 4 nm/min. At temperatures lower than 300° C., insufficient growth speeds can be observed, however, in certain embodiments lower temperatures can be acceptable.

Various nucleation layers can be employed, e.g., undoped SiGe, doped silicon (preferably B-doped), or undoped silicon. Each of the layers (nucleation layer, CVD layer, and PECVD or PACVD layer) can independently be optionally doped with the same or different doping or dopants, or can be undoped. Each layer can have a different doping concentration.

### Comparative Example 1—PECVD or PACVD at 520° C.

A first series of films were deposited at 520° C. Deposition conditions and properties of the films are provided in Table 1. PECVD was used to take advantage of the higher growth rates. At 520° C., growth rates up to 140 nm/min were observed. These films had very low resistivity values (0.6-1.0 mΩcm) and were expected to be polycrystalline.

TABLE 1
Measurement Results for PECVD Films Deposited at 520° C.

| Wafer temp. | SiH₄ flow | Power | T_{deposit} | Stress | Thick | Rsheet_{sq} | ρ | Ge conc. |
|---|---|---|---|---|---|---|---|---|
| [° C.] | [sccm] | [W] | [min] | [MPa] | [μm] | [Ω] | [mΩcm] | [%] |
| 520 | 30 | 30 | 10 | Ct = +13 | 1.0-1.3 | 4.4-6.6 | 0.6-0.7 | 60 |
| | | | | Av = +9 | | | | |
| 520 | 50 | 30 | 10 | Ct = −8 | 1.1-1.5 | 4.4-6.6 | 0.6-0.8 | 53 |
| | | | | Av = −12 | | | | |
| 520 | 70 | 30 | 10 | Ct = −26 | 1.3-1.5 | 4.2-7.4 | 0.6-1.0 | 45 |
| | | | | Av = −37 | | | | |

It is noted that this temperature can be too high for some processes. For CMOS compatibility, lower temperatures (e.g. at 450° C. or lower) are recommended.

### Comparative Example 2—PECVD 450° C.

Boron and phosphorous doped PECVD SiGe films were deposited at 450° C. For the P-doped films, unacceptably high resistivity values (>10⁵ mΩcm) were obtained. Similarly, for B-doped films, a very high compressive stress and large resistivity values were obtained, indicating that the films were not polycrystalline but amorphous in nature.

### Comparative Example 3—CVD 450° C.

CVD films deposited at 450° C. had low resistivity values. Deposition conditions and properties of the films are provided in Table 2. The long deposition times make the process unsuitable for use in preparing thick films.

TABLE 2
Measurement Results for CVD Films Deposited at 450° C.
Using an Undoped PECVD Amorphous Si Nucleation Layer

| Wafer | | | | | | | | |
|---|---|---|---|---|---|---|---|---|
| temp. | SiH₄ flow | Power | T_{deposit} | Stress | Thick | Rsheet_{sq} | ρ | Ge conc. |
| [° C.] | [sccm] | [W] | [minutes] | [MPa] | [μm] | [Ω] | [mΩcm] | [%] |
| 450 | 30 | 0 | 120 | Ct = −28 | 1.9-2.5 | 2.7-2.8 | 0.6 | 64 |
| | | | | Av = −31 | | | | |
| 450 | 50 | 0 | 120 | Ct = −103 | 2.1-2.4 | 3.0-3.5 | 0.7 | 55 |
| | | | | Av = −105 | | | | |
| 450 | 70 | 0 | 120 | Ct = −167 | 1.8-2.0 | 3.0-4.0 | 0.6-0.7 | 47 |
| | | | | Av = −160 | | | | |

### Example 4—CVD+PECVD Films at 450° C.

Different variations of the process of preferred embodiments were investigated by varying the silane flow rates and deposition temperatures. A poly SiGe deposition was conducted as follows. A 5 min H₂ anneal is followed by a brief PECVD deposition at the specified plasma power to form a nucleation layer. The plasma power density range was about 60 mW/cm² (electrode diameter of approximately 25 cm). The gas flows were fixed at the following rates: 166 sccm 10% GeH₄ in H₂, 40 sccm 1% B₂H₆ in H₂. SiH₄ flow rate was varied and the chamber pressure was maintained at 2 Torr. Next, a 20 minute CVD step was conducted to deposit a CVD layer of about 370 nm in thickness. Finally, a PECVD processing step at the specified plasma power was carried out to deposit a PECVD layer of sufficient thickness to obtain the specified overall thickness of the poly SiGe layer. The deposition rate for this step was approximately 113 nm/min. The nucleation layer was B-doped SiGe.

The method for forming the poly-SiGe layer was performed at, respectively, 420, 435 and 450° C. The data demonstrate that for deposition at 450° C. a low stress, low resistivity layer is obtained at a reasonable deposition rate (39 nm/min for a total thickness of about 1 μm. Such a layer cannot be obtained by the use of PECVD alone. The overall or total deposition rate increases even more for thicker films, wherein the following fraction increases as follows:

$$\frac{deposition {time}_{PECVD}}{total deposition time}$$

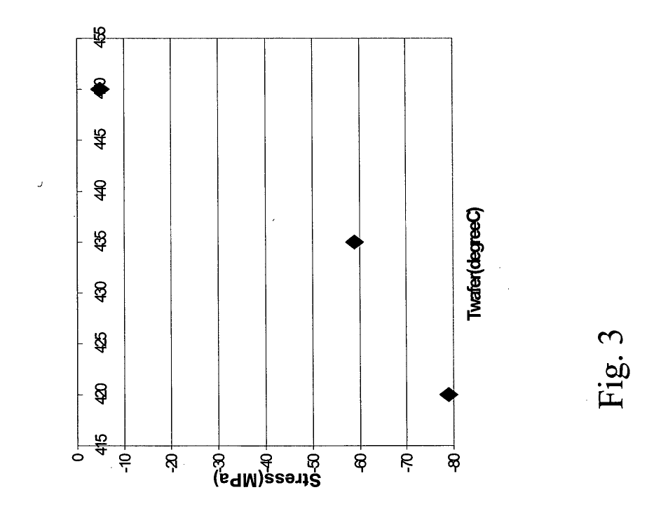

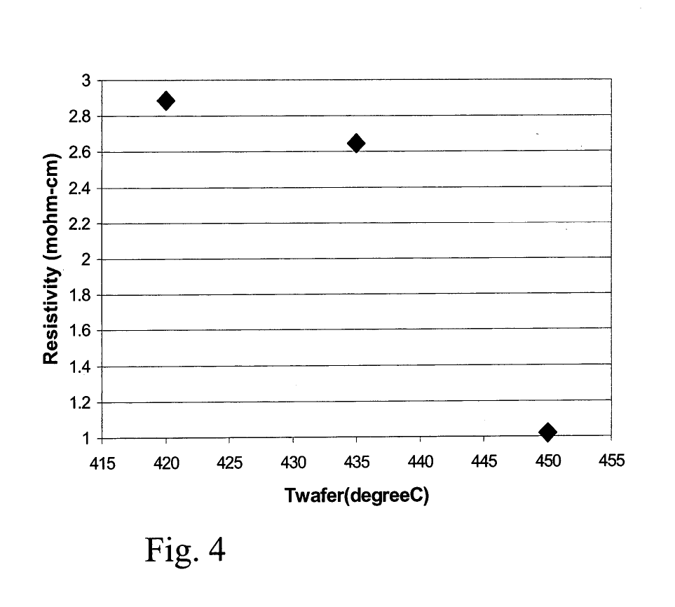

As can be seen in the data of Table 3, the films were more compressive and the resistivity values higher when the deposition temperature was decreased below 450° C. (see FIG. 3, which shows variation of average stress with deposition temperature for a poly SiGe layer, and FIG. 4, which shows variation of average resistivity with deposition temperature). While not wishing to be bound by any particular theory, it is believed that lowering the temperature reduces the crystallinity of the films, which is in accordance with the above observations.

TABLE 3
CVD + PECVD SiGe Films at Different Deposition Temperatures

| | | | Deposition time | | | | | |
|---|---|---|---|---|---|---|---|---|
| T_{wafer} | SiH₄ | Power | [‘ = minutes | Thickness | Stress | R_{sheetsq} | ρ | Ge conc. |
| [° C.] | [sccm] | [W] | “ = seconds] | [μm] | [MPa] | [ohm] | [mΩcm] | [%] |
| ˜420 | 30 | (30+) | 50″ PECVD | 0.9-1.0 | Ct = −72 | 14-45 | 1.4-4.0 | 66 |
| | | 0 + 30 | nucleation+ 20′CVD + 6′ | | Av = −79 | | | |
| | | | PECVD | | | | | |
| ˜435 | 30 | (30+) | 50″ PECVD | 0.8-1.0 | Ct = −50 | 13-47 | 1.3-3.8 | 66 |
| | | 0 + 30 | nucleation+ 20′CVD + 5′30″ | | Av = −59 | | | |
| | | | PECVD | | | | | |
| ˜450 | 30 | (30+) | 50″ PECVD | 0.9-1.1 | Ct = −0.6 | 7-13 | 0.8-1.2 | 65 |
| | | 0 + 30 | nucleation+ 20′CVD + 5′ | | Av = −5 | | | |
| | | | PECVD | | | | | |

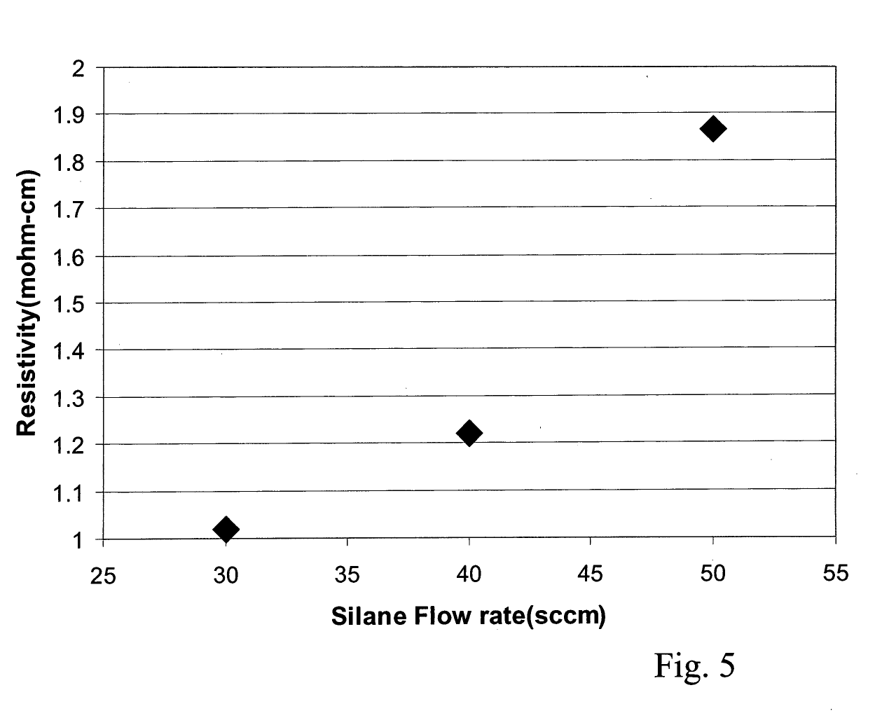

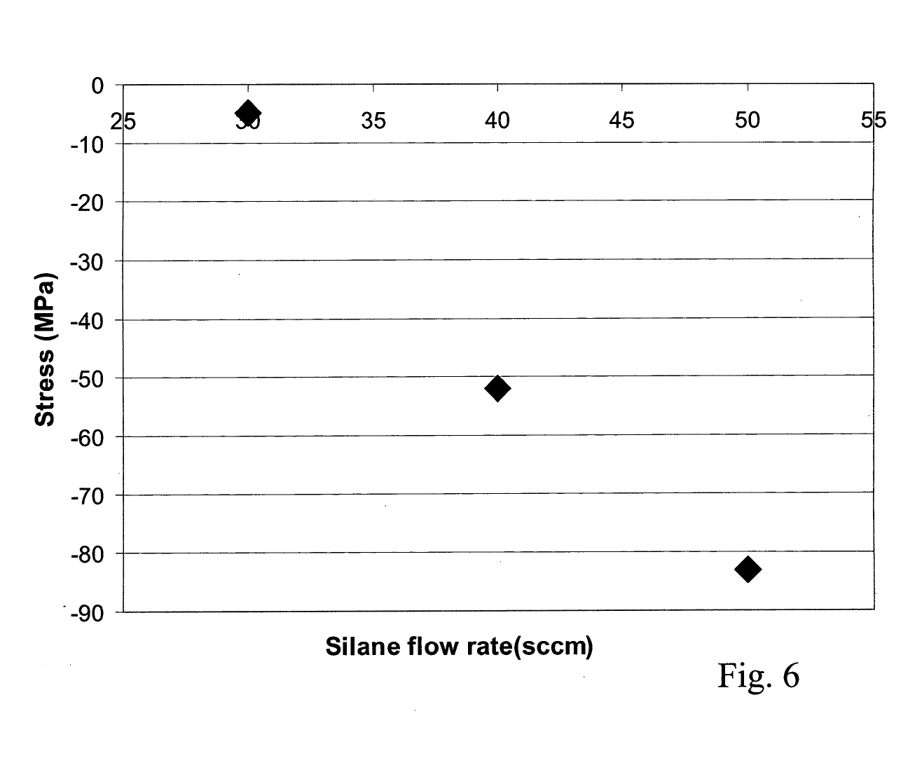

The method for forming a poly SiGe layer was also performed for different silane flow rates (30, 40 and 50 sccm, respectively) at a deposition temperature of 450° C. Data for the resulting layers is provided in Table 4. As the GeH₄/SiH₄ ratio increased, the Ge concentration in the film also increased. The RBS data shows a sharp fall in the germanium concentration with the increase in silane concentration. An increase in Ge concentration reduced the amorphous to crystalline transition temperature, thus it is believed that this increase resulted in more crystalline films at lower temperatures. It is expected that more crystalline films have lower resistivity values. This can be clearly observed in FIG. 5, which provides data regarding variation of average resistivity with silane flow rate. Also, the compressive stresses in films increases as the silane flow increases, as shown in FIG. 6, which shows variation of average stress with silane flow rate.

TABLE 4
CVD + PECVD Films at Silane Flow Rates of 30, 40 and 50 sccm

| | | | Deposition time | | | | | Ge |
|---|---|---|---|---|---|---|---|---|
| T_{wafer} | SiH₄ | Power | [‘ = min | Thickness | Stress | R_{sheetsq} | ρ | conc. |
| [° C.] | [sccm] | [W] | “ = seconds] | [μm] | [MPa] | [ohm] | [mΩcm] | [%] |
| ˜450 | 30 | (30+) 0 + 30 | 50″ PECVD | 0.9-1.1 | Ct = −0.6 | 7-13 | 0.8-1.2 | 65 |
| | | | nucleation+ 20′ | | Av = −5 | | | |
| | | | CVD + 5′ PECVD | | | | | |
| ˜450 | 40 | (30+) 0 + 30 | 50″ PECVD | 0.9-1.1 | Ct = −43 | 9-15 | 1.0-1.4 | 60 |
| | | | nucleation+ 20′ | | Av = −52 | | | |
| | | | CVD + 4′48″ | | | | | |
| | | | PECVD | | | | | |
| ˜450 | 50 | (30+) 0 + 30 | 50″ PECVD | 0.9-1.1 | Ct = −78 | 11-28 | 1.2-2.5 | 56 |
| | | | nucleation+ 20′ | | Av = −83 | | | |
| | | | CVD + 4′36″ | | | | | |
| | | | PECVD | | | | | |

A 1 μm poly SiGe film (450° C.) was deposited as follows. A 5 minute H₂ anneal was conducted to ensure temperature uniformity across the wafer. 50 seconds PECVD flash yielding a thin nucleation SiGe layer of approximately 94 nm thickness, 20 minutes CVD step at 2 Torr with 30 sccm SiH4, 166 sccm 10% GeH₄ in H₂ and 40 sccm 1% B₂H₆ in H₂ to form a CVD layer of approximately 370 nm thickness. 5 minutes PECVD with the same gas flows and pressure, and 30 W plasma power to form a PECVD layer. The film thus prepared exhibited an average compressive stress of −5 MPa and an average resistivity value of 1.0 mΩcm. The RBS data showed a germanium concentration of 65% in the PECVD layer.

Table 5 illustrates the relationship between the overall or total deposition time and the fraction:

$$\frac{deposition {time}_{PECVD}}{total deposition time}$$

wherein:
total deposition time=deposition time_{nucleation PECVD}+deposition time_{CVD}+deposition time_{PECVD}
The deposition time_{nucleation} PECVD and the deposition time_{CVD} were fixed at 50 seconds and 20 minutes, respectively. The resulting overall deposition rate increased for thicker films, with the following fraction increasing:

$$\frac{deposition {time}_{PECVD}}{total deposition time}$$

The deposition process marked with an asterisk (*) in Table 5 was performed with a PECVD deposited amorphous silicon layer instead of a PECVD SiGe layer. All films had a low resistivity and a low stress, and were suitable for surface micromachining.

TABLE 5

| PECVD deposition | Total deposition | | | | | |
|---|---|---|---|---|---|---|
| time | time | | | | | Deposition |
| [‘ = min | [‘ = min | Thickness | Stress | ρ | Ge conc. | rate |
| “ = seconds] | “ = seconds] | [μm] | [MPa] | [mΩ-cm] | [%] | [nm/min] |
| 5′ | 25′ 50″ | 0.9-1.1 | Ct = −0.6 | 0.8-1.2 | 65 | 39 |
| | | | Av = −5 | | | |
| 10′ (*) | 30′ 50″ | 1.5-1.7 | Av = +20 | 0.9-1 | Not | 53 |
| | | | | | measured | |
| 84′ 24″ | 105′ 14″ | 10-13 | Av = +71 | 0.9 | 64 | 109 |

In Table 6, data is presented illustrating the superior properties of poly SiGe layers prepared according to the preferred embodiments.

TABLE 6
Comparison Between Conventional Methods (Power = 0, 30) and
Method of Preferred Embodiment (Power = 0 + 30)

| T_{wafer} | SiH₄ | Power | Deposition time | Stress | Thickness | ρ | |
|---|---|---|---|---|---|---|---|
| [° C.] | [sccm] | [W] | [minutes] | [MPa] | [μm] | [mΩcm] | Crystalline? |
| 450 | 30 | 0 (CVD) | 120 | Av = −31 | 1.9-2.5 | 0.6 | Yes |
| 450 | 30 | 30 (PECVD) | 10 | Av = −104 | not | >10e⁴ | No |
| | | | | | measured | | |
| 450 | 30 | 0 + 30 | 20 + 10 | Av = +20 | 1.5-1.7 | 0.9-1 | Yes |

From the above results certain optimized operation conditions can be determined. For example, the optimum value for x is a function of Tn (the time for preparing the nucleation layer), the optimum value for y is a function of T1 (the time for preparing the CVD layer), and the optimum value for z is a function of T2 (the time for preparing the PECVD or PACVD layer). Preferably, Tn=T1=T2=T. Under such conditions, T is preferably about 450° C. and 0.50≦1-z≦0.70, more preferably 0.60≦1-z≦0.70.

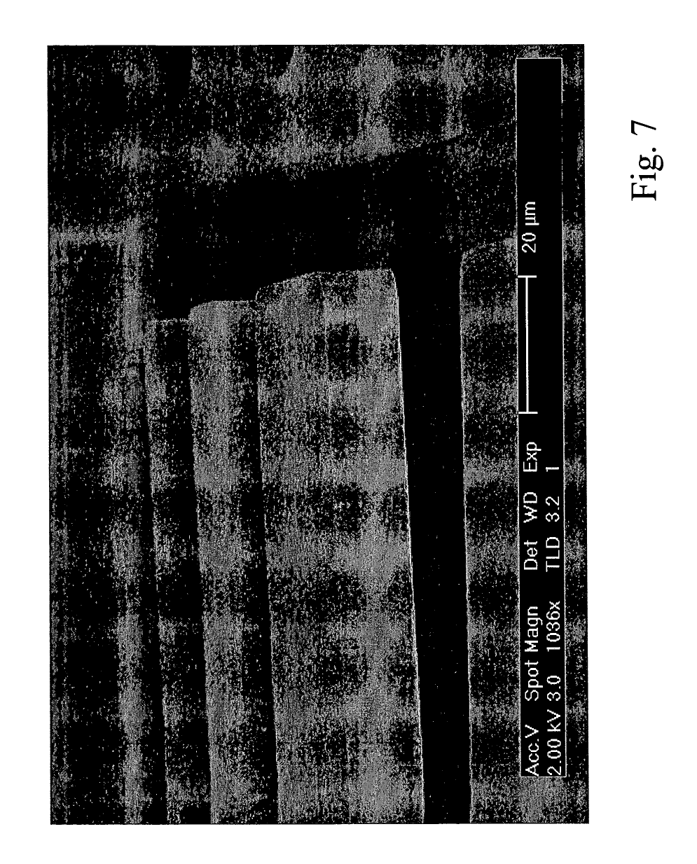

FIG. 7 shows free cantilevers formed in a SiGe layer deposited in accordance with a preferred embodiment. Such microstructures can be formed above layers comprising semiconductor active components, e.g., components as formed by CMOS processing.

The above description discloses several methods and materials of the present invention. This invention is susceptible to modifications in the methods and materials, as well as alterations in the fabrication methods and equipment. Such modifications will become apparent to those skilled in the art from a consideration of this disclosure or practice of the invention disclosed herein. Consequently, it is not intended that this invention be limited to the specific embodiments disclosed herein, but that it cover all modifications and alternatives coming within the true scope and spirit of the invention as embodied in the attached claims. All patents, applications, and other references cited herein are hereby incorporated by reference in their entirety.

1. A method of producing a polycrystalline SiGe layer on a substrate, the method comprising:
a) depositing onto the substrate a first layer comprising a polycrystalline silicon-germanium, wherein the depositing comprises non-plasma chemical vapor deposition conducted at a first temperature less than or equal to about 520° C.; and
b) depositing onto the first layer a second layer comprising a polycrystalline silicon-germanium, wherein the depositing comprises plasma enhanced chemical vapor deposition or plasma assisted chemical vapor deposition at a second temperature less than or equal to about 520° C., whereby a polycrystalline SiGe layer comprising the first layer and the second layer is obtained.

2. The method according to claim 1, further comprising:
depositing a nucleation layer onto the substrate at a third temperature less than or equal to about 520° C., wherein the depositing is conducted before step a).

3. The method according to claim 2, wherein the nucleation layer comprises silicon or SiₓGe₁₋ₓ wherein 0.10≦x.

4. The method according to claim 1, wherein the first layer comprises Si_{y}Ge_{1-y} wherein 0.10≦y≦1.

5. The method according to claim 1, wherein the first layer comprises Si_{y}Ge_{1-y} wherein 0.50≦1-y≦0.70.

6. The method according to claim 1, wherein the second layer comprises Si_{z}Ge_{1-z} wherein 0.10≦z≦1.

7. The method according to claim 1, wherein the second layer comprises Si_{z}Ge_{1-z} wherein 0.50≦1-z≦0.70.

8. The method according to claim 1, wherein the first temperature, the second temperature, and the third temperature are each less than or equal to about 500° C.

9. The method according to claim 1, wherein the first temperature, the second temperature, and the third temperature are each less than or equal to about 450° C.

10. The method according to claim 1, wherein the first temperature equals the second temperature, and the second temperature equals the third temperature.

11. The method according to claim 1, wherein the first temperature equals the second temperature, the second temperature equals the third temperature, and the third temperature equals about 450° C.

12. The method according to claim 11, wherein the second layer comprises Si_{z}Ge_{1-z} wherein 0.50≦1-z≦0.70.

13. The method according to claim 11, wherein the second layer comprises Si_{z}Ge_{1-z} wherein 0.60≦1-z≦0.70.

14. The method according to claim 1, wherein step a) and step b) are performed at a pressure of from about 1 to about 10 Torr.

15. The method according to claim 1, wherein a plasma power is from about 10 to about 100 W.

16. The method according to claim 1, wherein a plasma power density is from about 20 to about 200 mW/cm².

17. The method of claim 1, wherein the polycrystalline SiGe layer has an electrical resistance of less than about 10 mΩcm.

18. The method of claim 1, wherein the polycrystalline SiGe layer has a compressive stress of less than about 20 MPa and a tensile stress of less than about 100 MPa.

19. A method of producing a polycrystalline SiGe layer on a substrate, the method comprising:
a) depositing onto the substrate a first layer comprising a polycrystalline silicon-germanium by a non-plasma chemical vapor deposition technique at a temperature of less than or equal to 520° C. and at a rate of less than about 10 nm/min; and
b) depositing onto the first layer a second layer comprising a polycrystalline silicon-germanium by a plasma enhanced chemical vapor deposition technique at a temperature of less than or equal to 520° C. and at a rate of about 50 nm/min or more, whereby a polycrystalline SiGe layer comprising the first layer and the second layer is obtained.

20. The method of claim 19, wherein step b) is conducted at a rate of about 100 nm/min or more.
